(19) United States
(12) Patent Application Publication
(10) Pub. No.: US 2026/0029470 A1
(43) Pub. Date: Jan. 29, 2026

(54) HYBRID TIME FREQUENCY DOMAIN SYSTEM AND METHOD FOR BATTERY CELL STATE ESTIMATION

(71) Applicants: GM Global Technology Operations LLC, Detroit, MI (US); Auburn University, Auburn, AL (US)

(72) Inventors: Taylor Reed Garrick, Bloomfield Hills, MI (US); Erin Efimoff, Oak Park, MI (US); Song-Yul Choe, Auburn, AL (US)

(73) Assignees: GM Global Technology Operations LLC, Detroit, MI (US); Auburn University, Auburn, MI (US)

(21) Appl. No.: 18/780,960

(22) Filed: Jul. 23, 2024

(51) Int. Cl. G01R 31/367; B60L 58/13; G01R 31/36; G01R 31/374; G01R 31/3835

(52) U.S. Cl. CPC G01R 31/367; B60L 58/13; G01R 31/3648; G01R 31/374; G01R 31/3835

(57) ABSTRACT

A method of battery cell state estimation includes measuring an initial temperature of a cell grouping in a vehicle, applying a perturbation to the cell grouping in the vehicle for a threshold period of time, and measuring a perturbation temperature of the cell grouping and a voltage of the cell grouping. The method also includes calculating, based on the measured perturbation temperature of the cell grouping and the measured voltage of the cell grouping, an entropy coefficient of the cell grouping, and determining a plateau location based on the measured voltage of the cell grouping. The method further includes generating a state of charge estimate based on the entropy coefficient and the plateau location, and splitting the state of charge estimate and the entropy coefficient into a material level state of lithiation and a material level entropy coefficient.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates generally to estimating battery cell state using hybridized time and frequency domain analysis. In particular, lithium-ion batteries are widely used as highly efficient energy storage devices in electric and hybrid vehicles. Here, when energy is stored in and/or retrieved from the battery, heat is generated. This heat raises the temperature of the battery, thereby affecting the performance of the battery and contributing to degradation of the battery. As such, it is critical to accurately understand the effects of the heat sources on the battery so that subsequent cooling systems and operations can be optimized to improve performance of the battery.

The entropy coefficient of a lithium-ion battery at any given moment is a key parameter in determining the amount of reversible heat generated during the operation of a battery. However, traditional methods of measuring the entropy coefficient and a resulting state of charge (SOC) of the battery may take a prohibitive amount of measurement time. As such, there is a need for a faster method of measuring the entropy coefficient while limiting the drift of relaxation voltage of the battery.

### SUMMARY

One aspect of the disclosure provides a computer-implemented method that when executed on data processing hardware causes the data processing hardware to perform operations that include measuring an initial temperature of a cell grouping in a vehicle, applying a perturbation to the cell grouping in the vehicle for a threshold period of time, and measuring a perturbation temperature of the cell grouping and a voltage of the cell grouping. The operations also include calculating, based on the measured perturbation temperature of the cell grouping and the measured voltage of the cell grouping, an entropy coefficient of the cell grouping, and determining a plateau location based on the measured voltage of the cell grouping. The operations further include generating a state of charge estimate based on the entropy coefficient and the plateau location and splitting the state of charge estimate and the entropy coefficient into a material level state of lithiation and a material level entropy coefficient.

Implementations of the disclosure may include one or more of the following optional features. In some implementations, the operations further include predicting a reversible heat generation for a specific load using the material level state of lithiation and the material level entropy coefficient. In some examples, the perturbation is applied to the cell grouping using Peltier elements. In these examples, the cell grouping may include three (3) cells. Each cell of the cell grouping may include a corresponding Peltier element. Optionally, each Peltier element is in contact with a face of the corresponding cell of the cell grouping. Alternatively, each Peltier element is in contact with an internal cooling fin inside the corresponding cell of the cell grouping.

In some implementations, applying the perturbation to the cell grouping in the vehicle includes applying one of a sinusoidal temperature perturbation a triangle wave perturbation, or a square wave perturbation. In these implementations, the perturbation may have an amplitude of five (5) degrees Celsius. In some examples, the entropy coefficient of the cell grouping is calculated using one of i) a Fourier transform of the measured perturbation temperature of the cell grouping and the measured voltage of the cell grouping, or ii) a trace of the measured voltage of the cell grouping by the measured perturbation temperature of the cell grouping.

Another aspect of the disclosure provides a system including data processing hardware and memory hardware in communication with the data processing hardware. The memory hardware stores instructions that when executed by the data processing hardware cause the data processing hardware to perform operations that include measuring an initial temperature of a cell grouping in a vehicle, applying a perturbation to the cell grouping in the vehicle for a threshold period of time, and measuring a perturbation temperature of the cell grouping and a voltage of the cell grouping. The operations also include calculating, based on the measured perturbation temperature of the cell grouping and the measured voltage of the cell grouping, an entropy coefficient of the cell grouping, and determining a plateau location based on the measured voltage of the cell grouping. The operations further include generating a state of charge estimate based on the entropy coefficient and the plateau location and splitting the state of charge estimate and the entropy coefficient into a material level state of lithiation and a material level entropy coefficient.

This aspect may include one or more of the following optional features. In some implementations, the operations further include predicting a reversible heat generation for a specific load using the material level state of lithiation and the material level entropy coefficient. In some examples, the perturbation is applied to the cell grouping using Peltier elements. In these examples, the cell grouping may include three (3) cells. Each cell of the cell grouping may include a corresponding Peltier element. Optionally, each Peltier element is in contact with a face of the corresponding cell of the cell grouping. Alternatively, each Peltier element is in contact with an internal cooling fin inside the corresponding cell of the cell grouping.

In some implementations, applying the perturbation to the cell grouping in the vehicle includes applying one of a sinusoidal temperature perturbation a triangle wave perturbation, or a square wave perturbation. In these implementations, the perturbation may have an amplitude of five (5) degrees Celsius. In some examples, the entropy coefficient of the cell grouping is calculated using one of i) a Fourier transform of the measured perturbation temperature of the cell grouping and the measured voltage of the cell grouping, or ii) a trace of the measured voltage of the cell grouping by the measured perturbation temperature of the cell grouping.

The details of one or more implementations of the disclosure are set forth in the accompanying drawings and the description below. Other aspects, features, and advantages will be apparent from the description and drawings, and from the claims.

### BRIEF DESCRIPTION OF THE DRAWINGS

The drawings described herein are for illustrative purposes only of selected configurations and are not intended to limit the scope of the present disclosure.

FIG. 1 is a schematic view of an example system for battery cell state estimation.

FIG. 2 is a schematic view of example components of the system of FIG. 1.

FIG. 3 is a perturbation waveform of the system of FIG. 1.

FIG. 4. is a frequency domain transformation of FIG. 1.

FIG. 5 is a state of charge plot of FIG. 1.

FIG. 6 is a flowchart of an example arrangement of operations for a method of battery cell state estimation.

Corresponding reference numerals indicate corresponding parts throughout the drawings.

### DETAILED DESCRIPTION

Example configurations will now be described more fully with reference to the accompanying drawings. Example configurations are provided so that this disclosure will be thorough, and will fully convey the scope of the disclosure to those of ordinary skill in the art. Specific details are set forth such as examples of specific components, devices, and methods, to provide a thorough understanding of configurations of the present disclosure. It will be apparent to those of ordinary skill in the art that specific details need not be employed, that example configurations may be embodied in many different forms, and that the specific details and the example configurations should not be construed to limit the scope of the disclosure.

The terminology used herein is for the purpose of describing particular exemplary configurations only and is not intended to be limiting. As used herein, the singular articles “a,” “an,” and “the” may be intended to include the plural forms as well, unless the context clearly indicates otherwise. The terms “comprises,” “comprising,” “including,” and “having,” are inclusive and therefore specify the presence of features, steps, operations, elements, and/or components, but do not preclude the presence or addition of one or more other features, steps, operations, elements, components, and/or groups thereof. The method steps, processes, and operations described herein are not to be construed as necessarily requiring their performance in the particular order discussed or illustrated, unless specifically identified as an order of performance. Additional or alternative steps may be employed.

When an element or layer is referred to as being “on,” “engaged to,” “connected to,” “attached to,” or “coupled to” another element or layer, it may be directly on, engaged, connected, attached, or coupled to the other element or layer, or intervening elements or layers may be present. In contrast, when an element is referred to as being “directly on,” “directly engaged to,” “directly connected to,” “directly attached to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The terms “first,” “second,” “third,” etc. may be used herein to describe various elements, components, regions, layers and/or sections. These elements, components, regions, layers and/or sections should not be limited by these terms. These terms may be only used to distinguish one element, component, region, layer or section from another region, layer or section. Terms such as “first,” “second,” and other numerical terms do not imply a sequence or order unless clearly indicated by the context. Thus, a first element, component, region, layer or section discussed below could be termed a second element, component, region, layer or section without departing from the teachings of the example configurations.

In this application, including the definitions below, the term “module” may be replaced with the term “circuit.” The term “module” may refer to, be part of, or include an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor (shared, dedicated, or group) that executes code; memory (shared, dedicated, or group) that stores code executed by a processor; other suitable hardware components that provide the described functionality; or a combination of some or all of the above, such as in a system-on-chip.

The term “code,” as used above, may include software, firmware, and/or microcode, and may refer to programs, routines, functions, classes, and/or objects. The term “shared processor” encompasses a single processor that executes some or all code from multiple modules. The term “group processor” encompasses a processor that, in combination with additional processors, executes some or all code from one or more modules. The term “shared memory” encompasses a single memory that stores some or all code from multiple modules. The term “group memory” encompasses a memory that, in combination with additional memories, stores some or all code from one or more modules. The term “memory” may be a subset of the term “computer-readable medium.” The term “computer-readable medium” does not encompass transitory electrical and electromagnetic signals propagating through a medium, and may therefore be considered tangible and non-transitory memory. Non-limiting examples of a non-transitory memory include a tangible computer readable medium including a nonvolatile memory, magnetic storage, and optical storage.

The apparatuses and methods described in this application may be partially or fully implemented by one or more computer programs executed by one or more processors. The computer programs include processor-executable instructions that are stored on at least one non-transitory tangible computer readable medium. The computer programs may also include and/or rely on stored data.

A software application (i.e., a software resource) may refer to computer software that causes a computing device to perform a task. In some examples, a software application may be referred to as an “application,” an “app,” or a “program.” Example applications include, but are not limited to, system diagnostic applications, system management applications, system maintenance applications, word processing applications, spreadsheet applications, messaging applications, media streaming applications, social networking applications, and gaming applications.

The non-transitory memory may be physical devices used to store programs (e.g., sequences of instructions) or data (e.g., program state information) on a temporary or permanent basis for use by a computing device. The non-transitory memory may be volatile and/or non-volatile addressable semiconductor memory. Examples of non-volatile memory include, but are not limited to, flash memory and read-only memory (ROM)/programmable read-only memory (PROM)/erasable programmable read-only memory (EPROM)/electronically erasable programmable read-only memory (EEPROM) (e.g., typically used for firmware, such as boot programs). Examples of volatile memory include, but are not limited to, random access memory (RAM), dynamic random access memory (DRAM), static random access memory (SRAM), phase change memory (PCM) as well as disks or tapes.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” and “computer-readable medium” refer to any computer program product, non-transitory computer readable medium, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

Various implementations of the systems and techniques described herein can be realized in digital electronic and/or optical circuitry, integrated circuitry, specially designed ASICS (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

The processes and logic flows described in this specification can be performed by one or more programmable processors, also referred to as data processing hardware, executing one or more computer programs to perform functions by operating on input data and generating output. The processes and logic flows can also be performed by special purpose logic circuitry, e.g., an FPGA (field programmable gate array) or an ASIC (application specific integrated circuit). Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, one or more aspects of the disclosure can be implemented on a computer having a display device, e.g., a CRT (cathode ray tube), LCD (liquid crystal display) monitor, or touch screen for displaying information to the user and optionally a keyboard and a pointing device, e.g., a mouse or a trackball, by which the user can provide input to the computer. Other kinds of devices can be used to provide interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

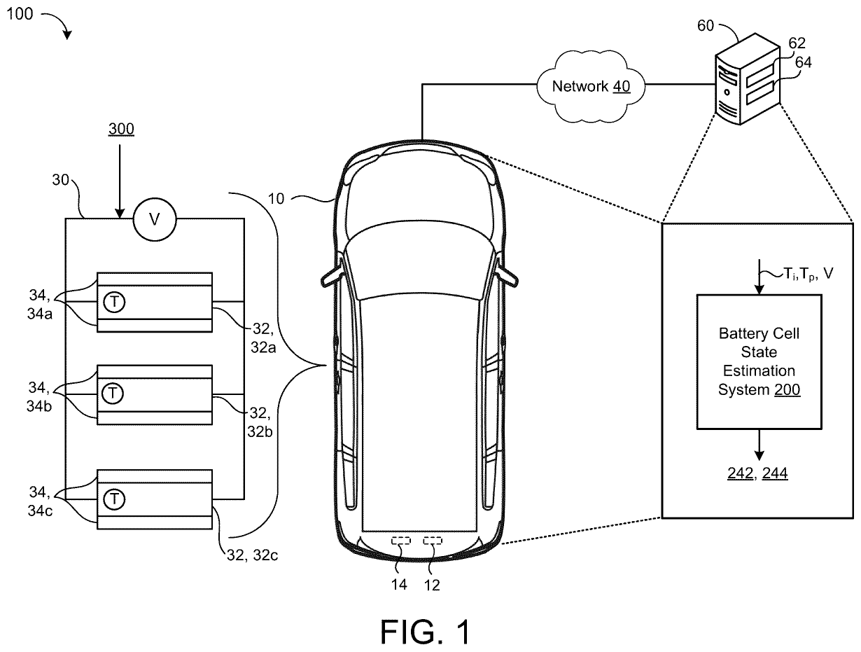

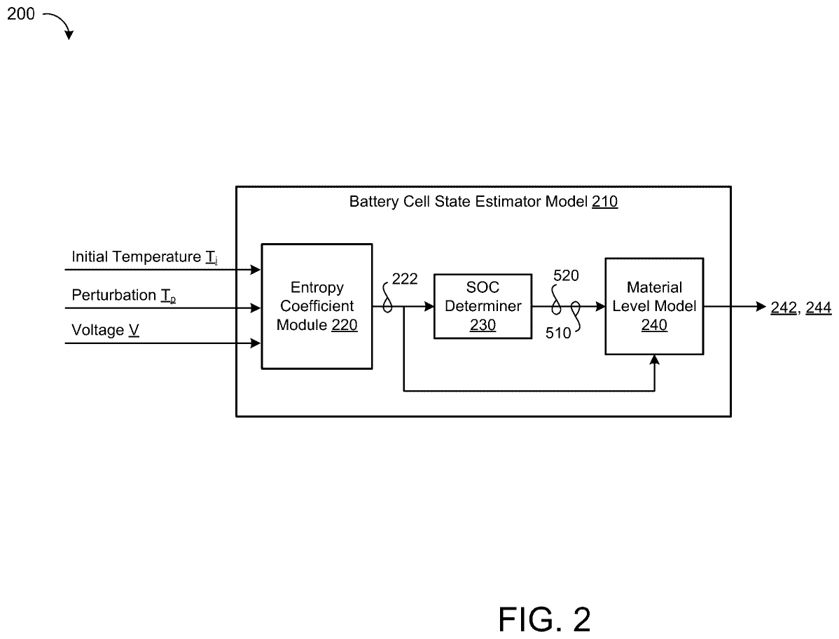

Referring to FIG. 1, in some implementations, a system 100 includes a vehicle 10 and/or a remote system 60 in communication with the vehicle 10 via a network 40. The vehicle 10 and/or the remote system 60 execute a battery cell state estimation system 200 (FIG. 2) configured to measure a change in temperature T and voltage V in a cell grouping 30 of the vehicle 10 in response to an applied perturbation 300 and determine a state of charge (SOC) estimate 520 of the cell grouping 30 to feed internal model variables such as fast charge protocols, maximum currents of the vehicle 10, coolant failure detections, etc. Briefly, and as described in further detail below, the battery cell state estimation system 200 applies the perturbation 300 to the cell grouping 30 and measures the perturbation temperature Tₚ and the perturbation voltage V in the cell grouping 30. Thereafter, the perturbation temperature Tₚ and the perturbation voltage V are transformed to the frequency domain to determine an entropy coefficient 222 of the cell grouping 30, which may be used in combination with known plateaus 510 to identify the SOC estimate 520 of the cell grouping 30. Notably, by transforming the temperature perturbation Tp and the voltage V from the time domain to the frequency domain, the battery cell state estimation system 200 removes the impact of voltage drift and the overpotential in the calculation of the entropy coefficient 222 and the resulting SOC estimate 520. Moreover, the entropy coefficient 222 is a key parameter of the battery grouping 30 (e.g., a lithium-ion battery) that determines the amount of reversible heat generated during operations of the vehicle 10.

In the examples shown, the battery cell state estimation system 200 is implemented within the vehicle 10. However, the battery cell state estimation system 200 can be implemented on other computing devices (e.g., computing devices in communication with the vehicle 10), such as, without limitation, a smart phone, tablet, smart display, desktop/laptop, smart watch, smart appliance, or smart glasses/headset. The vehicle 10 includes data processing hardware 12 and memory hardware 14 storing instructions that when executed on the data processing hardware 12 cause the data processing hardware 14 to perform operations. The vehicle 10 further includes the cell grouping 30 of a battery pack that supplies power to drive the vehicle 10. As shown, the cell grouping 30 includes three (3) cells 32, however it should be appreciated that the cell grouping 30 may include any number of cells 30. For example, in some implementations the cell grouping 30 includes two (2) cells 32. In other implementations, the cell grouping 30 includes one (1) cell 34. In further implementations, the cell grouping 30 may include four (4) or more cells 32. Moreover, it should be appreciated that the battery pack of the vehicle 10 may include a plurality of the cell groupings 30. In some implementations, each cell 32 may include a cathode with a flat equilibrium potential paired with an anode (e.g., graphite) having a flat equilibrium potential.

As shown, each cell 32a-32c in the cell grouping 30 includes a corresponding Peltier element 34, 34a-34c configured to transfer heat from one side of the cell 32 to the other side of the cell 32 (e.g., in response to instructions from the data processing hardware 12 of the vehicle 10). In the example, each Peltier element 34 is in contact with a face of the corresponding cell 32 of the cell grouping 30. However, in other implementations, each Peltier element 34 may be in contact with an internal cooling fin (not shown) inside the corresponding cell 32 of the cell grouping 30 so that each Peltier element 34 may add or remove heat from its corresponding cell 32 of the cell grouping 30.

The remote system 60 (e.g., server, cloud computing environment) also includes data processing hardware 62 and memory hardware 64 storing instructions that when executed on the data processing hardware 62 cause the data processing hardware 62 to perform operations. In some examples, execution of the battery cell state estimation system 200 is shared across the vehicle 10 and the remote system 60. As described in greater detail below with reference to FIGS. 2-6, the battery cell state estimation system 200 executing on the vehicle 10 and/or the remote system 60 executes a battery cell state estimation model 210 including an entropy coefficient module 220, a state of charge (SOC) determiner 230, and a material level model 240, and is configured to receive the measured temperature T and voltage V of the cell grouping 30, and generate, as output, a material level state of lithiation 242 and a material level entropy coefficient 244 of the cell grouping 30.

With reference to FIGS. 1 and 2, while the cell grouping 30 of the vehicle 10 is in a low state mode, the battery cell state estimation system 200 measures the initial temperature Tᵢ of the cell grouping 30. As used herein, the low state mode generally refers to instances where the cell grouping 30 is under a low load, such as, without limitation, when the vehicle 10 is parked, during light highway driving, sitting in traffic, etc. By measuring the initial temperature Tᵢ of the cell grouping 30, the battery cell state estimation system 200 may deconvolute any voltage drift from a voltage to a temperature signal initiated by the battery cell state estimation system 200.

After measuring the initial temperature Tᵢ of the cell grouping 30, the battery cell state estimation system 200 applies (via the Peltier elements 34) a perturbation 300 to each corresponding cell 32 of the cell grouping 30 for a threshold amount of time. Here, the battery cell state estimation system 200 applies the perturbation 300 to the cell grouping 30 for a threshold amount of time for the given chemistry of the cell grouping 30 to yield a clean enough temperature and voltage signal to be processed by the battery cell state estimation system 200. For example, the battery cell state estimation system 200 may send instructions to the Peltier elements 34 to apply the perturbation 300 for two (2) periods for a total of ten (10) minutes. However, it should be appreciated that the threshold amount of time may be configurable/changed based on the chemistry of the cell grouping 30 of the vehicle 10.

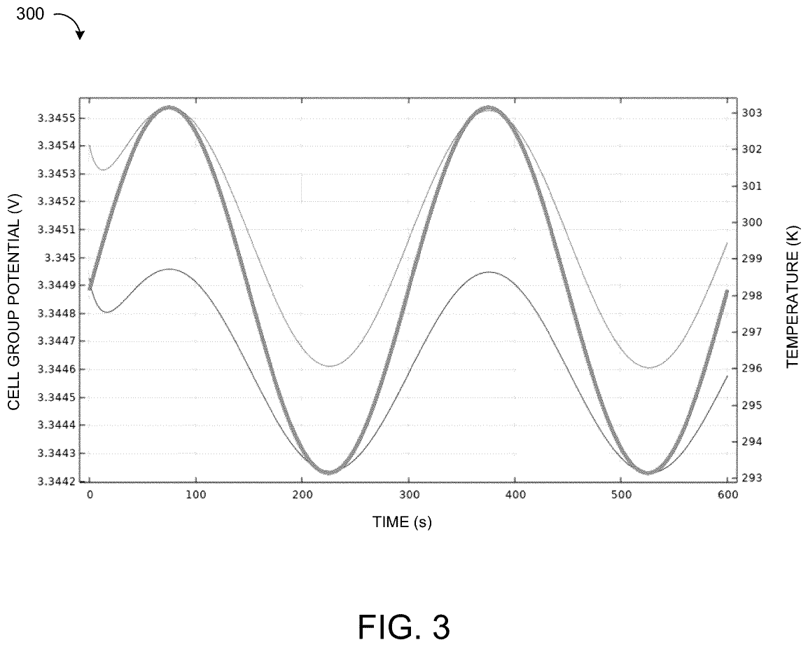

Referring briefly to FIG. 3, the perturbation 300 is shown. The perturbation 300 may be applied to the cell grouping 30 using an amplitude of approximately five (5) degrees Celsius at periods of five (5) minutes. For instance, as shown, perturbation 300 includes two (2) periods, with an x-axis of time(s) from 0 to 600 (e.g., 10 minutes), a primary y-axis of the voltage V of the cell grouping 30, and a secondary y-axis of the temperature T of the cell grouping 30. In some implementations, the perturbation 300 includes a sinusoidal temperature perturbation. In other implementations, the perturbation 300 includes a triangle wave perturbation. In alternate implementations, the perturbation 300 includes a square wave perturbation. Notably, the amplitude of the perturbation 300 may be configurable as well. For instance, the perturbation 300 may include any amplitude significant enough to provide a signal to determine the entropy coefficient 222. Here, an amplitude higher than five (5) degrees Celsius may improve effects of the perturbation 300 with respect to signal to noise.

Referring again to FIGS. 1 and 2, after applying the perturbation 300, the battery cell state estimation system 200 measures the cell grouping 30 to determine the response of the cell grouping 30 to the perturbation 300. In particular, the battery cell state estimation system 200 measures a perturbation temperature Tₚ of the cell grouping 30 and a voltage V of the cell grouping 30. The perturbation temperature Tₚ may generally refer to the temperature of the cell grouping 30 in response to the applied waveform of the perturbation 300. Likewise, the measured voltage V may include the voltage response of the cell grouping 30 in response to the applied waveform of the perturbation 300.

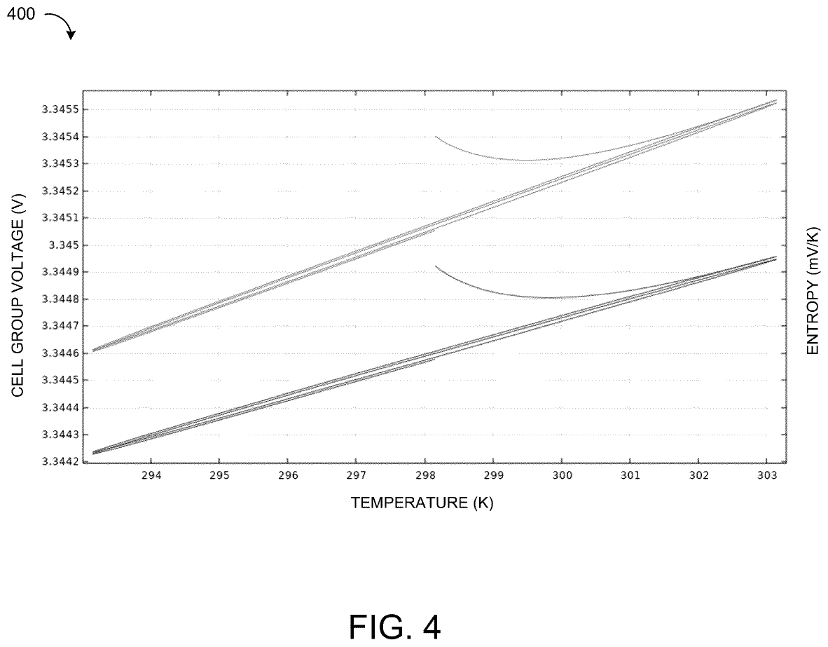

The entropy coefficient module 220 of the battery cell state estimation model 210 may receive the measured initial temperature Ti, the perturbation temperature Tp, and the voltage V as input, and generate, as output, an entropy coefficient 222 of the cell grouping 30. Here, the entropy coefficient module 220 receives the input signal of the perturbation temperature Tp and the voltage V and transforms the perturbation temperature Tp and the voltage V from the time domain to the frequency domain. For example, the entropy coefficient module 220 may calculate the entropy coefficient 222 by taking the Fourier transform of the input perturbation temperature Tp and the voltage V. In other examples, the entropy coefficient module 220 calculates the entropy coefficient 222 by taking the trace voltage V by the perturbation temperature Tp and taking the average derivative of the voltage V with respect to temperature T (dV/dT). For example, as shown in FIG. 4, the trace 400 of the voltage V with respect to the perturbation temperature Tp is shown with an x-axis of temperature (Kelvin), a primary y-axis of voltage (V), and a secondary y-axis of entropy (mV/K).

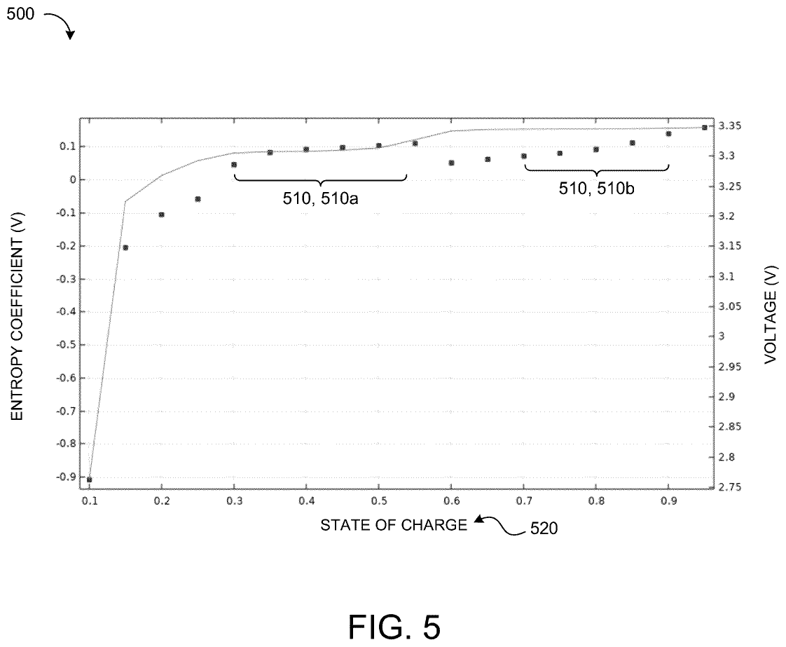

After the entropy coefficient module 220 calculates/generates the entropy coefficient 222, the SOC determiner 230 of the battery cell state estimate model 210 may determine one or more plateau locations 510 based on the measured voltage V of the cell grouping 30. For example, as shown in FIG. 5, the SOC determiner 230 may generate the plot 500 having an x-axis of SOC, a primary y-axis of the entropy coefficient, and a secondary y-axis of voltage (V). Here, the SOC determiner 230 may determine the plateau locations 510a, 510b in the plot 500. In particular, the plateau location 510a may range from 0.30 to 0.55 and the plateau location 510b may range from 0.70 to 0.90. Thereafter, the SOC determiner 230 generates an SOC estimate 520 based on the entropy coefficient 222 and the one or more plateau locations 510.

Once the battery cell state estimate system 200 generates the SOC estimate 520, the battery cell state estimate system 200 may use the SOC estimate 520 and the entropy coefficient 222 to feed internal model variables in the vehicle 10. Referring to FIG. 2, the material level model 240 of the battery cell state estimate model 210 receives, as input, the SOC estimate 520 and the entropy coefficient 222, and splits the SOC estimate 520 and the entropy coefficient 222 to generate/output a material level state of lithiation 242 and a material level entropy coefficient 244 of the cell grouping 30. As used herein, material level may refer to the anode and the cathode of each cell 32 in the cell grouping 30, where the amount of lithium in each of the anode and the cathode may dictate the performance of the cell 32.

In some implementations, the battery cell state estimate system 200 may feedforward the material level state of lithiation 242 and the material level entropy coefficient 244 of the cell grouping 30 to predict the reversible heat generation for a specific load of the cell grouping 30. For instance, the battery cell state estimate system 200 may use the material level state of lithiation 242 and the material level entropy coefficient 244 of the cell grouping 30 to calculate the half-cell state of lithiation of the battery of the vehicle 10. In other implementations, the material level state of lithiation 242 and the material level entropy coefficient 244 of the cell grouping 30 may be used to detect a coolant failure. For example, the material level state of lithiation 242 and the material level entropy coefficient 244 may be used to detect the coolant failure, and further determine the maximum power that can be drawn/requested from the cell grouping 30 (i.e., the battery pack) without triggering a thermal event in the cell grouping 30. Here, the material level state of lithiation 242 and the material level entropy coefficient 244 of the cell grouping 30 may account for the reversible heat generation of the cell grouping 30. Notably, this heat source term is not captured by the resistance of the cell 32 of the cell grouping 30. As such, accounting for this reversible heat in addition to the heat to the resistance of the cell 32 of the cell grouping 30 is critical when predicting or preventing thermal events in the cell grouping 30. While heat due to the resistance of the cell 32 may depend on other factors aside from the material level state of lithiation 242 and the material level entropy coefficient 244, calculating the material level state of lithiation 242 and the material level entropy coefficient 244 prevents excluding any heat source terms when predicting or preventing thermal events in the cell grouping 30. In other examples, where the material level coefficient 244 is negative (i.e., has a cooling effect), the material level state of lithiation 242 and the material level entropy coefficient 244 may be used to determine that the vehicle 10 may drive faster (e.g., 25 miles per hour versus 5 miles per hour) in a limp home scenario.

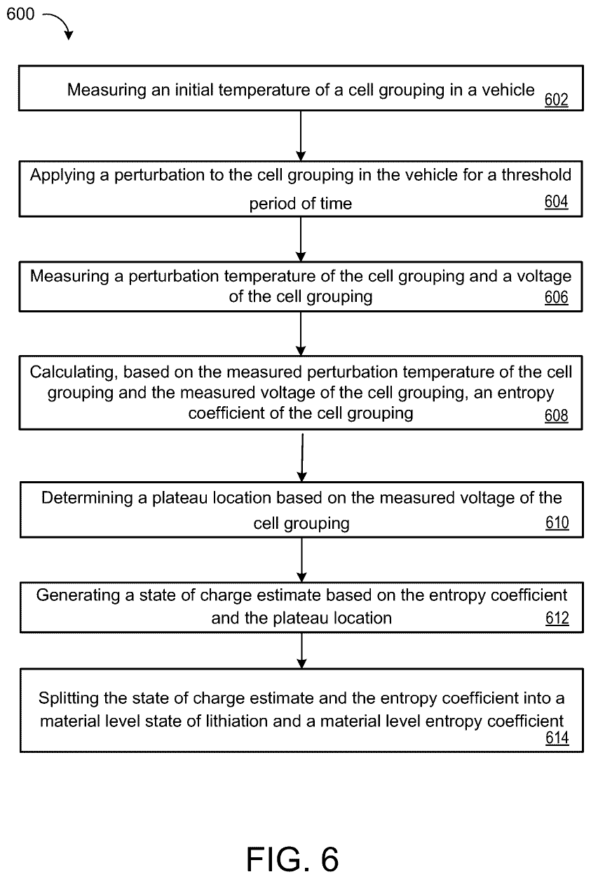

FIG. 6 shows a flowchart of an example arrangement of operations for a method 600 of battery cell state estimation. The method 600 may be described with reference to FIGS. 1-5. Data processing hardware (e.g., data processing hardware 12, 62 of FIG. 1) may execute instructions stored on memory hardware (e.g., memory hardware 14, 64 of FIG. 1) to perform the example arrangement of operations for the method 600.

At operation 602, the method 600 includes measuring an initial temperature Tᵢ of a cell grouping 30 in a vehicle 10. The method 600 also includes, at operation 604, applying a perturbation 300 to the cell grouping 30 in the vehicle 10 for a threshold period of time. At operation 606, the method 600 also includes measuring a perturbation temperature Tₚ of the cell grouping 30 and a voltage V of the cell grouping 30.

The method 600 also includes, at operation 608, calculating, based on the measured perturbation temperature Tₚ of the cell grouping 30 and the measured voltage V of the cell grouping 30, an entropy coefficient 222 of the cell grouping 30. At operation 610, the method 600 also includes determining a plateau location 510 based on the measured voltage V of the cell grouping 30. The method 600 further includes, at operation 612, generating a state of charge (SOC) estimate 520 based on the entropy coefficient 222 and the plateau location 510. At operation 614, the method 600 also includes splitting the SOC estimate 520 and the entropy coefficient 222 into a material level state of lithiation 242 and a material level entropy coefficient 244.

A number of implementations have been described. Nevertheless, it will be understood that various modifications may be made without departing from the spirit and scope of the disclosure. Accordingly, other implementations are within the scope of the following claims.

The foregoing description has been provided for purposes of illustration and description. It is not intended to be exhaustive or to limit the disclosure. Individual elements or features of a particular configuration are generally not limited to that particular configuration, but, where applicable, are interchangeable and can be used in a selected configuration, even if not specifically shown or described. The same may also be varied in many ways. Such variations are not to be regarded as a departure from the disclosure, and all such modifications are intended to be included within the scope of the disclosure.

What is claimed is:

1. A computer-implemented method when executed on data processing hardware causes the data processing hardware to perform operations comprising:
measuring an initial temperature of a cell grouping in a vehicle;
applying a perturbation to the cell grouping in the vehicle for a threshold period of time;
measuring a perturbation temperature of the cell grouping and a voltage of the cell grouping;
calculating, based on the measured perturbation temperature of the cell grouping and the measured voltage of the cell grouping, an entropy coefficient of the cell grouping;
determining a plateau location based on the measured voltage of the cell grouping;
generating a state of charge estimate based on the entropy coefficient and the plateau location; and
splitting the state of charge estimate and the entropy coefficient into a material level state of lithiation and a material level entropy coefficient.

2. The method of claim 1, wherein the operations further comprise predicting a reversible heat generation for a specific load using the material level state of lithiation and the material level entropy coefficient.

3. The method of claim 1, wherein the perturbation is applied to the cell grouping using Peltier elements.

4. The method of claim 3, wherein the cell grouping comprises three (3) cells.

5. The method of claim 4, wherein each cell of the cell grouping comprises a corresponding Peltier element.

6. The method of claim 5, wherein each Peltier element is in contact with a face of the corresponding cell of the cell grouping.

7. The method of claim 5, wherein each Peltier element is in contact with an internal cooling fin inside the corresponding cell of the cell grouping.

8. The method of claim 1, wherein applying the perturbation to the cell grouping in the vehicle comprises applying one of:
a sinusoidal temperature perturbation,
a triangle wave perturbation, or
a square wave perturbation.

9. The method of claim 8, wherein the perturbation has an amplitude of five (5) degrees Celsius.

10. The method of claim 1, wherein the entropy coefficient of the cell grouping is calculated using one of i) a Fourier transform of the measured perturbation temperature of the cell grouping and the measured voltage of the cell grouping, or ii) a trace of the measured voltage of the cell grouping by the measured perturbation temperature of the cell grouping.

11. A system comprising:
data processing hardware; and
memory hardware in communication with the data processing hardware, the memory hardware storing instructions that when executed on the data processing hardware cause the data processing hardware to perform operations comprising:
measuring an initial temperature of a cell grouping in a vehicle;
applying a perturbation to the cell grouping in the vehicle for a threshold period of time;
measuring a perturbation temperature of the cell grouping and a voltage of the cell grouping;
calculating, based on the measured perturbation temperature of the cell grouping and the measured voltage of the cell grouping, an entropy coefficient of the cell grouping;
determining a plateau location based on the measured voltage of the cell grouping;
generating a state of charge estimate based on the entropy coefficient and the plateau location; and
splitting the state of charge estimate and the entropy coefficient into a material level state of lithiation and a material level entropy coefficient.

12. The system of claim 11, wherein the operations further comprise predicting a reversible heat generation for a specific load using the material level state of lithiation and the material level entropy coefficient.

13. The system of claim 11, wherein the perturbation is applied to the cell grouping using Peltier elements.

14. The system of claim 13, wherein the cell grouping comprises three (3) cells.

15. The system of claim 14, wherein each cell of the cell grouping comprises a corresponding Peltier element.

16. The system of claim 15, wherein each Peltier element is in contact with a face of the corresponding cell of the cell grouping.

17. The system of claim 15, wherein each Peltier element is in contact with an internal cooling fin inside the corresponding cell of the cell grouping.

18. The system of claim 11, wherein applying the perturbation to the cell grouping in the vehicle comprises applying one of:
a sinusoidal temperature perturbation,
a triangle wave perturbation, or
a square wave perturbation.

19. The system of claim 18, wherein the perturbation has an amplitude of five (5) degrees Celsius.

20. The system of claim 11, wherein the entropy coefficient of the cell grouping is calculated using one of i) a Fourier transform of the measured perturbation temperature of the cell grouping and the measured voltage of the cell grouping, or ii) a trace of the measured voltage of the cell grouping by the measured perturbation temperature of the cell grouping.
